(19) United States
(12) Patent Application Publication
(10) Pub. No.: US 2025/0151597 A1
(43) Pub. Date: May 8, 2025

(54) METHOD FOR MANUFACTURING LIGHT-EMITTING ELEMENT, METHOD FOR MANUFACTURING DISPLAY PANEL, AND DISPLAY PANEL

(71) Applicant: HKC CORPORATION LIMITED, Shenzhen (CN)

(72) Inventors: YAO LI, Shenzhen (CN); Lidan YE, Shenzhen (CN)

(21) Appl. No.: 18/931,151

(22) Filed: Dec. 2, 2024

(30) Foreign Application Priority Data
Nov. 7, 2023 (CN) 202311470183.9

(51) Int. Cl. H10K 71/10; B07B 1/46; H10K 50/115; H10K 71/40

(52) U.S. Cl. CPC H10K 71/10; B07B 1/4663; H10K 50/115; H10K 71/40

(57) ABSTRACT

A method for manufacturing a light-emitting element includes: forming multiple hollow nanospheres of various sizes, wherein the hollow nanospheres are each filled with a respective light-emitting material; disposing the hollow nanospheres on a substrate; screening the hollow nanospheres so that they are stacked in layers the substrate according to their sizes, where the smaller the size of a hollow nanosphere, the closer it is to the substrate; heating the hollow nanospheres so that the hollow nanospheres are sublimed, and the respective light-emitting materials in the hollow nanospheres are stacked and distributed in layers on the substrate, thus forming a light-emitting element. The hollow nanospheres of an equal size are filled with an identical light-emitting material, and the hollow nanospheres of different sizes are filled with different light-emitting materials. The light-emitting materials are each an organic light-emitting material. A display panel and method for manufacturing the same are further disclosed.

### CROSS-REFERENCE TO RELATED APPLICATIONS

This application claims the priority and benefit of Chinese patent application number 2023114701839, titled “Method for Manufacturing Light-emitting Element, Method for Manufacturing Display Panel, and Display Panel” and filed Nov. 7, 2023 with China National Intellectual Property Administration, the entire contents of which are incorporated herein by reference.

### TECHNICAL FIELD

This application relates to the field of display technology, and more particularly relates to a method for manufacturing a light-emitting element, a method for manufacturing a display panel, and a display pane.

### BACKGROUND

The description provided in this section is intended for the mere purpose of providing background information related to the present application but doesn't necessarily constitute prior art.

Organic light emitting diodes (OLEDs) have the advantages of surface light source, cold light, energy saving, fast response, flexibility, ultra-thinness, and low cost. Furthermore, their mass production technology is becoming increasingly mature. The light-emitting element of OLED may be composed of thin films of three luminous colors, RGB, and a patterning process is required in the process of preparing the luminous thin films of the three colors. As a non-contact patterning technology, inkjet printing can directly pattern ink droplets at designated locations on a substrate. Another method is forming a light-emitting element by mask evaporation.

However, the light-emitting element in the OLED device has many film layers, including at least a hole injection layer, a hole transport layer, a light-emitting layer, an electron transport layer, and electron injection layer. Whether the inkjet printing or mask evaporation is used, each film layer needs to be prepared before the next film layer can be prepared, resulting in low preparation efficiency of the light-emitting elements and affecting the delivery speed of display panels. Therefore, how to improve the efficiency of the film-forming process of OLED light-emitting elements is crucial.

### SUMMARY

It is therefore one purpose of this application to provide a method for manufacturing a light-emitting element, a method for manufacturing a display panel, and a display panel to improve the efficiency of the-film forming process of the light-emitting element and improve the production efficiency of the display panel.

The present application discloses a method for manufacturing a light-emitting element, including:
forming hollow nanospheres of various sizes, wherein the hollow nanospheres are filled with light-emitting materials;
placing the hollow nanospheres of various sizes on a substrate;
performing screening to stack the hollow nanospheres of various sizes in layers on a substrate according to their sizes, and the smaller the size, the closer to the substrate;
heating the hollow nanospheres of various sizes to sublime the hollow nanospheres, and the light-emitting materials in the hollow nanospheres of different sizes are stacked and distributed in layers on the substrate to form a light-emitting element;
where the hollow nanospheres of an equal size are filled with an identical light-emitting material, and the hollow nanospheres of different sizes are filled with different light-emitting materials; the light-emitting material is an organic light-emitting material.

In some embodiments, the hollow nanospheres are formed of an iodine material.

In some embodiments, the radial width of the hollow nanosphere is greater than or equal to 50 nm and less than or equal to 500 nm, and the difference in radial widths of the hollow nanospheres corresponding to two adjacent light-emitting material layers is less than or equal to 50 nm.

In some embodiments, the hollow nanospheres of various sizes include a first nanosphere, a second nanosphere, a third nanosphere, a fourth nanosphere, and a fifth nanosphere with radial widths increasing in sequence. The radial width of the first nanosphere is 100 nm. The radial width of the second nanosphere is 150 nm. The radial width of the third nanosphere is 200 nm. The radial width of the fourth nanosphere is 250 nm. The radial width of the fifth nanosphere is 300 nm.

In some embodiments, the operation of placing the hollow nanospheres of various sizes on a substrate includes:
forming a bottom electrode on the substrate;
forming an isolation layer on the bottom electrode, forming a plurality of pixel openings on the isolation layer, and exposing the bottom electrode from the pixel openings.
where in the operation of performing screening to stack the hollow nanospheres of various sizes in layers on a substrate according to their sizes, and the smaller the size, the closer to the substrate, the hollow nanospheres of various sizes are screened in sequence using a multilayer molecular sieve structure;

The step of forming the light-emitting element includes forming a top electrode to form the light-emitting element.

In some embodiments, the operation of performing screening to stack the hollow nanospheres of various sizes in layers on a substrate according to their sizes where the smaller the size, the closer to the substrate includes:
stacking multiple layers of molecular sieve membranes of different screening sizes to form a multilayer molecular sieve structure;
screening out a layer of hollow nanospheres with the smallest size using the multilayer molecular sieve structure, and forming a layer of light-emitting material on the bottom electrode;
removing the molecular sieve membrane with the smallest screening size, and using the multilayer molecular sieve structure to continue screening the smallest hollow nanospheres among the remaining hollow nanospheres of various sizes, to form another layer of light-emitting material;
repeating the above operations in sequence until hollow nanospheres of various sizes are stacked in layers on the substrate according to their sizes;

The multilayer molecular sieve structure includes multiple layers of molecular sieve membranes with different filtration sizes, and the filtration sizes of the molecular sieve membranes are set in a one-to-one correspondence with the sizes of the hollow nanospheres.

In some embodiments, the light-emitting materials include a hole injection layer material, a hole transport layer material, a light-emitting layer material, an electron transport layer material, and an electron injection layer material;

The hole injection layer material is filled in the first nanosphere. The hole transport layer material is filled in the second nanosphere. The light-emitting layer material is filled in the third nanosphere. The electron transport layer material is filled in the fourth nanosphere. The electron injection layer material is filled in the fifth nanosphere.

In some embodiments, the step of heating the hollow nanospheres of the various sizes thus sublimating the hollow nanospheres and forming multiple light-emitting material layers on the substrate includes:
heating the substrate to a preset temperature;
the hollow nanospheres closer to the substrate sublimating first, and the hollow nanospheres in the direction away from the substrate gradually sublimating;
forming a light-emitting material layer with a multi-layer stacking arrangement.

The present application further discloses a method for manufacturing a display panel, comprising:
manufacturing a light-emitting element according to the above-mentioned method for manufacturing a light-emitting element;
forming an encapsulation layer;
forming a display panel.

The present application further discloses a display device, including a display panel formed by the above-mentioned manufacturing method.

In the present application, the multiple layers of light-emitting materials in the light-emitting element are respectively filled into hollow nanospheres of different sizes. In the step of forming multiple light-emitting material layers, different light-emitting materials can be separated from each other by size screening. Thus, it is possible to realize the simultaneous inkjet printing of multiple light-emitting material layers. After screening, a multi-layered structure composed of multiple light-emitting material layer can be formed. Compared with the technical solution of forming the various film layer in the light-emitting element layer by layer through inkjet printing in the exemplary technology, the present application forms multiple film layers in the light-emitting element through a one-step process, thereby simplifying the process, saving the time of the manufacturing process of the light-emitting elements, and thus improving the production efficiency of the light-emitting elements and the production efficiency of the display panel.

### BRIEF DESCRIPTION OF DRAWINGS

The accompanying drawings are used to provide a further understanding of the embodiments according to the present application, and constitute a part of the specification. They are used to illustrate the embodiments according to the present application, and explain the principles of the present application in conjunction with the text description. Apparently, the drawings in the following description merely represent some embodiments of the present disclosure, and for those having ordinary skill in the art, other drawings may also be obtained based on these drawings without investing creative. In the drawings:

FIG. 1 is a flowchart of a method for manufacturing a light-emitting element according to the present application.

FIG. 2 is a schematic diagram of a process of heating and sublimating hollow nanospheres according to the present application.

FIG. 3 is a schematic diagram of hollow nanospheres of various sizes according to the present application.

FIG. 4 is a schematic diagram of a multilayer molecular sieve structure according to the present application.

FIG. 5 is a schematic diagram of a light-emitting element according to the present application.

FIG. 6 is flowchart of a method for manufacturing a display panel according to the present application.

In the drawings: 100, light-emitting element; 100a, film particle; 101, hole injection layer; 102, hole transport layer; 103, light-emitting layer; 104, electron transport layer; 105, electron injection layer; 110, bottom electrode; 111, top electrode; 112, isolation column; 200, hollow nanosphere; 201, first nanosphere; 202, second nanosphere; 203, third nanosphere; 204, fourth nanosphere; 205, fifth nanosphere; 300, multilayer molecular sieve structure; 301, first molecular sieve membrane; 302, second molecular sieve membrane; 303, third molecular sieve membrane; 304, fourth molecular sieve membrane; 305, fifth molecular sieve membrane.

### DETAILED DESCRIPTION OF EMBODIMENTS

It should be understood that the terms used herein, the specific structures and functional details disclosed therein are merely representative for describing some specific embodiments, but the present application can be implemented in many alternative forms and should not be construed as being limited to only these embodiments described herein.

As used herein, terms “first”, “second”, or the like are merely used for illustrative purposes, and shall not be construed as indicating relative importance or implicitly indicating the number of technical features specified. Thus, unless otherwise specified, the features defined by “first” and “second” may explicitly or implicitly include one or more of such features. Terms “multiple”, “a plurality of”, and the like mean two or more. In addition, terms “up”, “down”, “left”, “right”, “vertical”, and “horizontal”, or the like are used to indicate orientational or relative positional relationships based on those illustrated in the drawings. They are merely intended for simplifying the description of the present disclosure, rather than indicating or implying that the device or element referred to must have a particular orientation or be constructed and operate in a particular orientation. Therefore, these terms are not to be construed as restricting the present disclosure. For those of ordinary skill in the art, the specific meanings of the above terms as used in the present application can be understood depending on specific contexts.

The present application will be described in detail below with reference to the accompanying drawings and some optional embodiments.

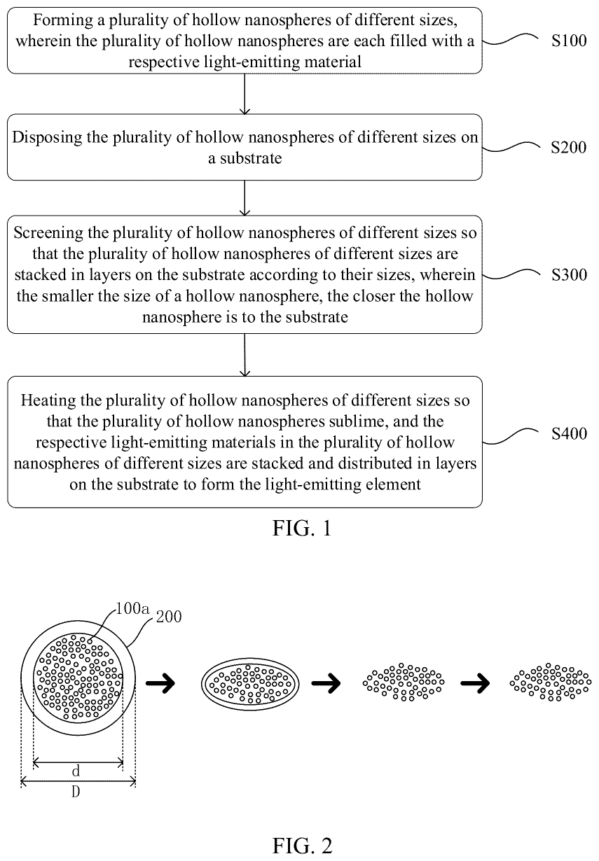

FIG. 1 is a flowchart of a method for making a light-emitting element according to the present application. As shown in FIG. 1, the present application discloses a method for making a light-emitting element, including the following operations:
S100: forming hollow nanospheres of various sizes, wherein the hollow nanospheres are filled with light-emitting materials;
S200: placing the hollow nanospheres of various sizes on a substrate;
S300: performing screening to stack the hollow nanospheres of various sizes in layers on a substrate according to their sizes, and the smaller the size, the closer to the substrate;
S400: heating the hollow nanospheres of various sizes to sublime the hollow nanospheres, and the light-emitting materials in the hollow nanospheres of different sizes are stacked and distributed in layers on the substrate to form a light-emitting element;
where the hollow nanospheres of an equal size are filled with an identical light-emitting material, and the hollow nanospheres of different sizes are filled with different light-emitting materials; the light-emitting material is an organic light-emitting material.

In the present application, the multiple layers of light-emitting materials in the light-emitting element are respectively filled into hollow nanospheres of different sizes. In the step of forming multiple light-emitting material layers, different light-emitting materials can be separated from each other by size screening. Thus, it is possible to realize the simultaneous inkjet printing of multiple light-emitting material layers. After screening, a multi-layered structure composed of multiple light-emitting material layer can be formed. Compared with the technical solution of forming the various film layer in the light-emitting element layer by layer through inkjet printing in the exemplary technology, the present application forms multiple film layers in the light-emitting element through a one-step process, thereby simplifying the process, saving the time of the manufacturing process of the light-emitting elements, and thus improving the production efficiency of the light-emitting elements and the production efficiency of the display panel.

As a non-contact patterning technology, inkjet printing can directly pattern ink droplets at designated locations on a substrate. Inkjet printing first melts the light-emitting material in a solvent to make it into an ink shape. The ink containing the light-emitting material is sprayed onto the substrate through a nozzle of an inkjet head, and printed between the gratings of the substrate. Finally, after the solvent is removed through the drying process, the printing of OLED materials is completed. Due to the technical characteristics of inkjet printing, each functional layer needs to be sprayed separately, and has to be dried before the next layer can be prepared. It can be understood that since the materials of each film layer in the light-emitting element are different, in the exemplary technology, each time a layer is printed with inkjet, it needs to go through processes such as loading, spraying, and drying to complete the production of a film layer. Moreover, when forming the next film layer, the inkjet device needs to be replaced, which is extremely time-consuming. For the Tandem OLED technology route with multiple layers of light-emitting materials, the preparation efficiency is extremely low, and the spraying precision in inkjet printing is also required to be extremely high.

In this application, film particles formed by different layers of light-emitting materials in the light-emitting element are wrapped in nanospheres of different sizes. Using the screening structure, hollow nanospheres of different sizes are screened and deposited so that they can be deposited in the required films stacking sequence. After the stacking of nanospheres in all film layers is completed, heating is performed to directly sublimate the nanospheres. The film particles wrapped inside will be released and form a film evenly, which can significantly increase the film formation rate of the organic light-emitting layer.

In S100, the preparation of the hollow nanosphere can use an ultrasonic chemical method, a hydrothermal method or a template method. In this step, the preparation of the hollow nanospheres and light-emitting materials can be completed in the material factory before they are directly transported to the panel factory, or directly produced in the panel factory. This application separates the preparation of hollow nanosphere from the process of display panel, and the two can be carried out simultaneously, further reducing the process time of the display panel.

Specifically, the hollow nanosphere is formed by an iodine material. Iodine can start to sublimate at a temperature of about 45 degrees and can be completely sublimated at about 77 degrees. In this embodiment, iodine material is selected as the material of hollow nanosphere. In the subsequent processes, the hollow nanosphere can be completely removed by heating to an appropriate temperature, leaving only the membrane layer particle to form a membrane layer. The process in which a solid substance evaporates directly into steam without going through a liquid process is called “sublimation”. Sublimation is an endothermic process. Sublimation may occur on the surface of any solid at room temperature and pressure. Iodine is a solid substance at room temperature and sublimates under slight heat. Iodine has low chemical activity and may not react with metals. It is worth mentioning that the hollow nanosphere of the present application includes but is not limited to iodine materials, and other materials with the same sublimation characteristics are also applicable to the present application.

Specifically, a radial width of the hollow nanosphere is greater than or equal to 50 nm and less than or equal to 500 nm. The radial width of the hollow nanosphere in the present application refers to the particle size of the hollow nanosphere, and in this embodiment, different light-emitting materials are distinguished mainly by judging the radial widths of the hollow nanospheres. The thickness of each film layer in the light-emitting element may be in the micron level. Correspondingly, in a film layer, a large number of hollow nanospheres are required for filling, and before the hollow nanospheres are sublimated, the formed films have a certain degree of flatness. Even after the hollow nanospheres are sublimated, the interface between the film layers can be guaranteed.

FIG. 2 is a schematic diagram illustrating a process of heating and sublimation of hollow nanospheres according to the present application. As shown in FIG. 2, a radial width of each hollow nanosphere 200 is D, and a hollow width of the hollow nanosphere 200 is d. The hollow nanosphere 200 is spherical before heating. After gradual heating, the hollow nanosphere 200 gradually ellipsoidizes until the hollow nanosphere is completely sublimated. The film particles 100a of the light-emitting material inside the hollow nanosphere is dispersed from the hollow nanosphere to form a light-emitting material layer. During the sublimation process, the spherical shape will deform as the spherical material sublimates. The thickness of the sphere gradually decreases, and the shape gradually becomes elliptical or flat. During the shape change process, the membrane layer particles contained in the sphere will also be redistributed along with the change of the spherical shape, and finally a flattening effect may be presented. After the sphere sublimates, the membrane layer particles will remain to form a film.

Specifically, the difference in radial widths of the hollow nanospheres corresponding to two adjacent light-emitting material layers is less than or equal to 50 nm. In this embodiment, the size difference of the hollow nanospheres corresponding to different light-emitting material layers cannot be too large to prevent the hollow nanospheres from being easily mixed together when forming a film layer due to the different sizes of the hollow nanospheres.

The display principle of OLED (Organic Light Emitting Diode) is simply the phenomenon of luminescence caused by carrier injection and recombination under the drive of an electric field. The principle is using an ITO transparent electrode and a metal electrode as the top electrode and bottom electrode of the device respectively. Under the drive of a certain voltage, electrons and holes are respectively injected from the top electrode and bottom electrode through the electron injection layer (EIL) and the hole injection layer (HIL) into the electron transport layer (ETL) and the hole transport layer (HTL), and then migrate to the emission layer (EML), where they meet to form excitons to excite the luminescent molecules, which emit visible light after radiation.

This application takes the five-layer film structure in the above-mentioned light-emitting element as an example for explanation. It can be understood that in actual situations, the size of the hollow nanosphere that can be designed in this application can vary with the number of film layers.

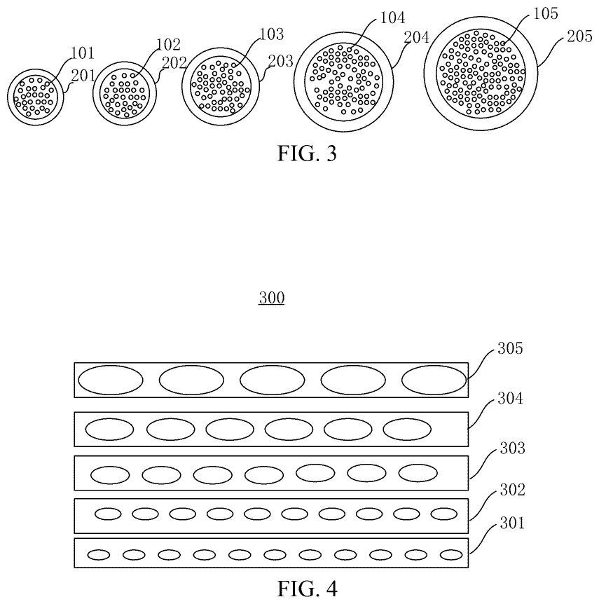

FIG. 3 is a schematic diagram of hollow nanospheres of various sizes according to the present application. As shown in FIG. 3, the hollow nanospheres 200 of various sizes include a first nanosphere 201, a second nanosphere 202, a third nanosphere 203, a fourth nanosphere 204, and a fifth nanosphere 205, which have increasing radial widths in sequence. The radial width of the first nanosphere 201 is 100 nm. The radial width of the second nanosphere 202 is 150 nm. The radial width of the third nanosphere 203 is 200 nm. The radial width of the fourth nanosphere 204 is 250 nm. The radial width of the fifth nanosphere 205 is 300 nm.

In this embodiment, when hollow nanospheres are subsequently screened using screening structures such as a molecular sieve, the minimum size difference between hollow nanospheres of different sizes is still 50 nm, so that the subsequent molecular sieve can better distinguish hollow nanospheres of different sizes.

The light-emitting materials include a hole injection layer 101 material, a hole transport layer 102 material, a light-emitting layer 103 material, an electron transport layer 104 material, and an electron injection layer 105 material. The hole injection layer 101 material is filled in the first nanosphere 201. The hole transport layer 102 material is filled in the second nanosphere 202. The light-emitting layer 103 material is filled in the third nanosphere 203. The electron transport layer 104 material is filled in the fourth nanosphere 204. The electron injection layer 105 material is filled in the fifth nanosphere 205.

Specifically, S200 includes:
S210: forming a bottom electrode on a substrate;
S211: forming an isolation layer on the bottom electrode, forming a plurality of pixel openings on the isolation layer, and exposing the bottom electrode from the pixel openings.

In the operation of S300, a multilayer molecular sieve structure is used to screen hollow nanospheres of various sizes in sequence.

In step S400, a top electrode is formed on the light-emitting material to form a light-emitting element.

In this embodiment, a multilayer molecular sieve structure is mainly used to screen hollow nanospheres of various sizes, and the multilayer molecular sieve has the function of distinguishing hollow nanospheres of various sizes from each other.

FIG. 4 is a schematic diagram of a multilayer molecular sieve structure according to the present application. As shown in FIG. 4, the multilayer molecular sieve structure 300 includes multiple layers of molecular sieve membranes, and each layer of molecular sieve membrane corresponds to a different screening size. Taking the five sizes of the hollow nanospheres as an example, five layers of molecular sieve membranes are provided in this embodiment, namely, a first molecular sieve membrane 301, a second molecular sieve membrane 302, a third molecular sieve membrane 303, a fourth molecular sieve membrane 304, and a fifth molecular sieve membrane 305, where their screening sizes increase in sequence. The first molecular sieve membrane 301 can screen out the first nanosphere 201, and the screening size is 100 nm. The second molecular sieve membrane 302 can allow the first nanosphere 201 and the second nanosphere 202 to pass through, and the screening size is 150 nm. The third molecular sieve membrane 303 can allow the first nanosphere 201, the second nanosphere 202, and the third nanosphere 203 to pass through, and the screening size is 200 nm. The fourth molecular sieve membrane 304 can allow the first nanosphere 201, the second nanosphere 202, the third nanosphere 203, and the fourth nanosphere 204 to pass through, and the screening size is 250 nm. The fifth molecular sieve membrane 305 can allow the first nanosphere 201, the second nanosphere 202, the third nanosphere 203, the fourth nanosphere 204, and the fifth nanosphere 205 to pass through, and the screening size is 300 nm.

In this embodiment, the first molecular sieve membrane 301, the second molecular sieve membrane 302, the third molecular sieve membrane 303, the fourth molecular sieve membrane 304, and the fifth molecular sieve membrane 305 are stacked in layers, with one above another. When the five layers of molecular sieve membranes are stacked together, only the first nanosphere with the smallest size can pass through, so that the first nanosphere can be completely screened out. After the first nanospheres are completely screened out, the first molecular sieve membrane is removed from the multilayer molecular sieve structure, and the remaining four layers of molecular sieve membranes are left to continue screening. At this time, the second nanospheres are screened out. Then the third nanospheres, the fourth nanospheres, and the fifth nanospheres are screened out in turn, so that a first nanosphere layer, a second nanosphere layer, a third nanosphere layer, a fourth nanosphere layer, and a fifth nanosphere layer are stacked in layers on the bottom electrode.

Specifically, the step S300 includes:
S310: stacking multiple layers of molecular sieve membranes of different screening sizes to form a multilayer molecular sieve structure;
S311: screening out a layer of hollow nanospheres with the smallest size using the multilayer molecular sieve structure, and forming a layer of light-emitting material on the bottom electrode;
S312: removing the molecular sieve membrane with the smallest screening size, and using the multilayer molecular sieve structure to continue screening the smallest hollow nanospheres among the remaining hollow nanospheres of various sizes, to form another layer of light-emitting material;
S313: repeating the above operations in sequence until hollow nanospheres of various sizes are stacked in layers on the substrate according to their sizes;

The multilayer molecular sieve structure includes multiple layers of molecular sieve membranes with different filtration sizes, and the filtration sizes of the molecular sieve membranes are set in a one-to-one correspondence with the sizes of the hollow nanospheres.

The screening operations S311-S313 in the present application can complete the screening of multiple hollow nanospheres of different sizes in one step. Then, multiple film layers are formed in a stacked arrangement, including but not limited to the hole injection layer, the hole transport layer, the light-emitting layer, the electron transport layer, and the electron injection layer mentioned above.

In one embodiment, all hollow nanospheres can be placed in an inkjet printing box. A multilayer molecular sieve structure is disposed in a nozzle of the inkjet printer. After each film layer is formed, the corresponding first molecular sieve membrane is removed, and the process is repeated in sequence to complete the production of the multiple film layers in the light-emitting element. It is worth mentioning that the multilayer molecular sieve structure of the present application can be reused, and the hollow nanospheres can be provided by the material factory, which can greatly improve the production efficiency of the display panel.

Specifically, S400 includes:
S410: heating the substrate to a preset temperature;
S411: the hollow nanospheres closer to the substrate sublimate first, and the hollow nanospheres in the direction facing away from the substrate gradually sublimate;
S412: forming a light-emitting material layer with a multi-layer stacking arrangement.

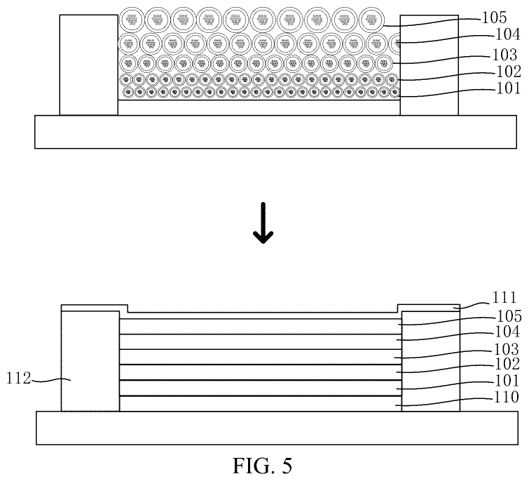

In this embodiment, the sublimation speed of the hollow nanospheres is related to the heating speed. The faster the heating, the faster the corresponding hollow nanosphere sublimates. In this scheme, heating is performed on one side of the substrate. It takes a certain amount of time for heat to be transferred, that is, it takes a certain amount of time for the hole injection layer on the substrate to be transferred to the electron injection layer. Therefore, the heat will be transferred to the hole injection layer first, and after the hollow nanosphere of the hole injection layer breaks and sublimates, the heat will gradually be transferred to the hole transport layer. Moreover, the hollow nanospheres of the hole injection layer absorb heat during sublimation and delay the time for the heat to reach the hole transport layer, so that after the hollow nanospheres of the hole injection layer are completely sublimated, the heat continues to enter the hollow transport layer. FIG. 5 is a schematic diagram of a light-emitting element according to the present application. As shown in FIG. 5, through the above process, the hole injection layer, the hole transport layer, the light-emitting layer, electron transport layer, and the electron injection layer in the light-emitting element can be made, which can be completed without a high temperature, and the performance of the light-emitting element is not affected at all.

In another embodiment, in order to make each film layer in the light-emitting element smoother, this embodiment can be used in combination with the multilayer molecular sieve structure to form a layer before forming the next film layer. The details are as follows:
S320: stacking multiple layers of molecular sieve membranes of different screening sizes to form a multilayer molecular sieve structure;
S321: screening out a layer of the smallest hollow nanospheres using the multilayer molecular sieve structure, thus forming a layer of hollow nanospheres filled with the hole injection layer material on the bottom electrode;
S322: heating the substrate to a preset temperature;
S323: the hollow nanosphere of the hole injection layer sublimes to form a hole injection layer;
S324: removing the molecular sieve membrane with the smallest screening size, and using the multilayer molecular sieve structure to continue screening the smallest hollow nanospheres among the remaining hollow nanospheres of various sizes, forming another layer of hollow nanospheres filled with the hole transport layer material;
S325: the hollow nanospheres of the hole transport layer sublimes to form a hole transport layer;
S326: repeating the above operations in sequence until hollow nanospheres of various sizes are stacked in layers on the substrate according to their sizes;
S327: form multiple layers of light-emitting material layers that are stacked in layers.

In this embodiment, after each layer of film particles is screened out through the multilayer molecular sieve structure, the substrate is heated to sublime the hollow nanospheres in the film particles, thereby directly completing the production of the respective film layer. After the film layer is prepared, the molecular sieve membrane of the corresponding film layer is removed to screen out the hollow nanosphere of the next film layer, and the heating process is repeated to form the next film layer. In this solution, since each layer of hollow nanospheres is sublimated separately, there will be no problem of film penetration between adjacent film layers, and a relatively better film layer interface can be formed.

In another embodiment, in order to ensure the uniformity of the hollow nanospheres falling on the substrate after screening from the molecular sieve structure, the substrate can be slightly shaken appropriately. The shaking direction is parallel to the bottom surface of the substrate to achieve better flatness of the film layer.

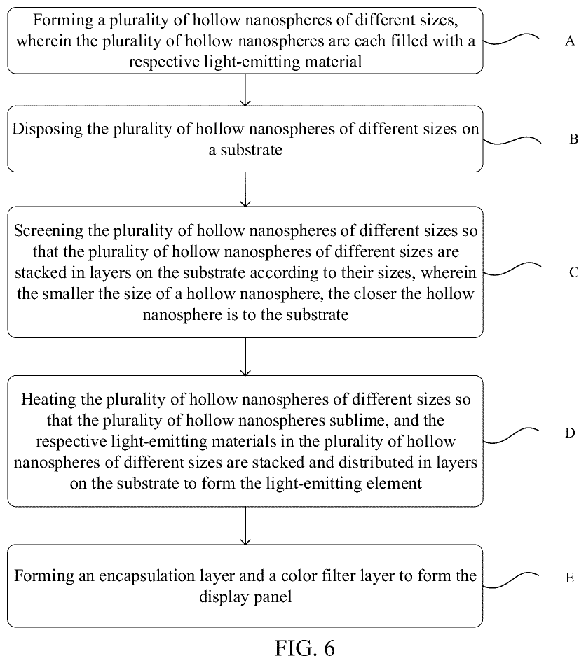

FIG. 6 is a flowchart of a method for manufacturing a display panel according to the present application. As shown in FIG. 6, the present application discloses a method for making a display panel, including:
A: forming hollow nanospheres of various sizes, wherein the hollow nanospheres are filled with light-emitting materials;
B: placing the hollow nanospheres of various sizes on a substrate;
C: performing screening to stack the hollow nanospheres of various sizes in layers on a substrate according to their sizes, and the smaller the size, the closer to the substrate;
D: heating the hollow nanospheres of various sizes to sublime the hollow nanospheres, and the light-emitting materials in the hollow nanospheres of different sizes are stacked and distributed in layers on the substrate to form a light-emitting element;
E: forming an encapsulation layer and a color filter layer to form a display panel.

Correspondingly, the present application further discloses a display device, including a display panel formed by the above-mentioned manufacturing method. It can be understood that the display panel mentioned in the present application is an OLED display panel, and the corresponding light-emitting element is an organic light-emitting element.

In the present application, the multiple layers of light-emitting materials in the light-emitting element are respectively filled into hollow nanospheres of different sizes. In the step of forming multiple light-emitting material layers, different light-emitting materials can be separated from each other by size screening. Thus, it is possible to realize the simultaneous inkjet printing of multiple light-emitting material layers. After screening, a multi-layered structure composed of multiple light-emitting material layer can be formed. Compared with the technical solution of forming the various film layer in the light-emitting element layer by layer through inkjet printing in the exemplary technology, the present application forms multiple film layers in the light-emitting element through a one-step process, thereby simplifying the process, saving the time of the manufacturing process of the light-emitting elements, and thus improving the production efficiency of the light-emitting elements and the production efficiency of the display panel.

It should be noted that the inventive concept of the present application can be formed into many embodiments, but the length of the application document is limited and so these embodiments cannot be enumerated one by one. Therefore, should no conflict be present, the various embodiments or technical features described above can be arbitrarily combined to form new embodiments. After the various embodiments or technical features are combined, the original technical effects may be enhanced.

The foregoing is a further detailed description of the present application with reference to some specific optional implementations, but it cannot be determined that the specific implementation of the present application is limited to these implementations. For those having ordinary skill in the technical field to which the present application pertains, several deductions or substitutions may be made without departing from the concept of the present application, and all these deductions or substitutions should be regarded as falling in the scope of protection of the present application.

What is claimed is:

1. A method for manufacturing a light-emitting element, comprising:
forming a plurality of hollow nanospheres of different sizes, wherein the plurality of hollow nanospheres are each filled with a respective light-emitting material;
disposing the plurality of hollow nanospheres of different sizes on a substrate;
screening the plurality of hollow nanospheres of different sizes so that the plurality of hollow nanospheres of different sizes are stacked in layers on the substrate according to their sizes, wherein the smaller the size of a hollow nanosphere, the closer the hollow nanosphere is to the substrate;
heating the plurality of hollow nanospheres of different sizes so that the plurality of hollow nanospheres sublime, and the respective light-emitting materials in the plurality of hollow nanospheres of different sizes are stacked and distributed in layers on the substrate to form the light-emitting element;
wherein the hollow nanospheres of an equal size are filled with an identical light-emitting material, and wherein the hollow nanospheres of different sizes are filled with different light-emitting materials; wherein the light-emitting materials are each an organic light-emitting material.

2. The method as recited in claim 1, wherein the plurality of hollow nanospheres area each formed of an iodine material.

3. The method as recited in claim 1, wherein the plurality of hollow nanospheres each have a radial width that is greater than or equal to 50 nm and less than or equal to 500 nm, and wherein a difference in radial widths of any two hollow nanospheres respectively corresponding to two adjacent layers of light-emitting material is less than or equal to 50 nm.

4. The method as recited in claim 1, wherein the plurality of hollow nanospheres of different sizes comprise a first nanosphere, a second nanosphere, a third nanosphere, a fourth nanosphere, and a fifth nanosphere, whose radial widths increase in sequence; wherein the first nanosphere has a radial width of 100 nm, wherein the second nanosphere has a radial width of 150 nm, wherein the third nanosphere has a radial width of 200 nm, wherein the fourth nanosphere has a radial width of 250 nm, wherein the fifth nanosphere has a radial width of 300 nm.

5. The method as recited in claim 1, wherein the operation of disposing the plurality of hollow nanospheres of different sizes on the substrate comprises:
forming a bottom electrode on a substrate; and
forming an isolation layer on the bottom electrode, defining a plurality of pixel openings in the isolation layer, and exposing the bottom electrode from the plurality of pixel openings;
wherein in the operation of screening the plurality of hollow nanospheres of different sizes so that the plurality of hollow nanospheres of different sizes are stacked in layers on a substrate according to their sizes, a multilayer molecular sieve structure is used to screen the plurality of hollow nanospheres of different sizes in sequence;
wherein the operation of forming a light-emitting element comprises forming a top electrode to form the light-emitting element.

6. The method as recited in claim 1, wherein the operation of screening the plurality of hollow nanospheres of different sizes so that the plurality of hollow nanospheres of different sizes are stacked in layers on a substrate according to their sizes comprises:
stacking a plurality of layers of molecular sieve membranes having different screening sizes to form a multilayer molecular sieve structure;
using the multilayer molecular sieve structure to screen out a layer of hollow nanospheres having the smallest size, and forming a layer of light-emitting material on the bottom electrode;
removing the molecular sieve membrane with the smallest screening size, and using the multilayer molecular sieve structure to continue screening out the hollow nanospheres having the smallest size among the remaining hollow nanospheres of different sizes, and forming another layer of light-emitting material;
repeating the above operations in sequence until the plurality of hollow nanospheres of different sizes are all stacked in layers on the substrate according to their sizes;
wherein the multilayer molecular sieve structure comprises a plurality of layers of molecular sieve membranes having different screening sizes, and wherein the screening sizes of the plurality of layers of molecular sieve membranes are set in one-to-one correspondence with the sizes of the hollow nanospheres.

7. The method as recited in claim 4, wherein the light-emitting materials comprise a hole injection layer material, a hole transport layer material, a light-emitting layer material, an electron transport layer material, and an electron injection layer material; wherein the hole transport layer material is filled in the first nanosphere; wherein the hole transport layer material is filled in the second nanosphere; wherein the light-emitting layer material is filled in the third nanosphere; wherein the electron transport layer material is filled in the fourth nanosphere; wherein the electron injection layer material is filled in the fifth nanosphere.

8. The method as recited in claim 1, wherein the operation of heating the plurality of hollow nanospheres of different sizes so that the plurality of hollow nanospheres sublime and the respective light-emitting materials in the plurality of hollow nanospheres of different sizes are stacked and distributed in layers on the substrate to form a light-emitting element comprises:
heating the substrate to a preset temperature so that each hollow nanospheres comparatively closer to the substrate sublime earlier than each another hollow nanosphere comparatively farther away from the substrate; and
forming a plurality of light-emitting material layers that are stacked one over another on the substrate.

9. The method as recited in claim 1, wherein the plurality of hollow nanospheres are prepared by a sonochemical method, a hydrothermal method, or a template method.

10. The method as recited in claim 1, wherein the operation of screening the plurality of hollow nanospheres of different sizes so that the plurality of hollow nanospheres of different sizes are stacked in layers on a substrate according to their sizes comprises:
S320: stacking a plurality of layers of molecular sieve membranes having different screening sizes to form a multilayer molecular sieve structure;
S321: using the multilayer molecular sieve structure to screen out a layer of hollow nanospheres having the smallest size, and forming a layer of hollow nanospheres filled with a hole injection layer material on the bottom electrode;
S322: heating the substrate to a preset temperature;
S323: the hollow nanospheres filled with the hole injection layer material subliming to form a hole injection layer;
S324: removing the molecular sieve membrane having the smallest screening size, and using the multilayer molecular sieve structure to continue screening the hollow nanospheres having the smallest size among the remaining hollow nanospheres of different sizes, and forming another layer of hollow nanospheres filled with a hole transport layer material;
S325: the hollow nanospheres filled with the hole transport layer material subliming to form a hole transport layer;
S326: repeating the above operations of S321-S325 in sequence until the plurality of hollow nanospheres of different sizes are all stacked in layers on the substrate according to their sizes; and
S327: forming a plurality of light-emitting material layers that are stacked one over another on the substrate.

11. A method for manufacturing a display panel, comprising:
forming a plurality of hollow nanospheres of different sizes, wherein the plurality of hollow nanospheres are each filled with a respective light-emitting material;
disposing the plurality of hollow nanospheres of different sizes on a substrate;
screening the plurality of hollow nanospheres of different sizes so that the plurality of hollow nanospheres of different sizes are stacked in layers on the substrate according to their sizes, wherein the smaller the size of a hollow nanosphere, the closer the hollow nanosphere is to the substrate;
heating the plurality of hollow nanospheres of different sizes so that the plurality of hollow nanospheres sublime, and the respective light-emitting materials in the plurality of hollow nanospheres of different sizes are stacked and distributed in layers on the substrate to form a light-emitting element; and
forming an encapsulation layer and a color filter layer to form the display panel;
wherein the hollow nanospheres of an equal size are filled with an identical light-emitting material, and wherein the hollow nanospheres of different sizes are filled with different light-emitting materials; wherein the light-emitting materials are each an organic light-emitting material.

12. The method as recited in claim 11, wherein the plurality of hollow nanospheres area each formed of an iodine material.

13. The method as recited in claim 11, wherein the plurality of hollow nanospheres each have a radial width that is greater than or equal to 50 nm and less than or equal to 500 nm, and wherein a difference in radial widths of any two hollow nanospheres respectively corresponding to two adjacent layers of light-emitting material is less than or equal to 50 nm.

14. The method as described in claim 11, wherein the plurality of hollow nanospheres of different sizes comprise a first nanosphere, a second nanosphere, a third nanosphere, a fourth nanosphere, and a fifth nanosphere, whose radial widths increase in sequence, wherein the first nanosphere has a radial width of 100 nm, wherein the second nanosphere has a radial width of 150 nm, wherein the third nanosphere has a radial width of 200 nm, wherein the fourth nanosphere has a radial width of 250 nm, wherein the fifth nanosphere has a radial width of 300 nm.

15. The method as recited in claim 11, wherein the operation of disposing the plurality of hollow nanospheres of different sizes on the substrate comprises:
forming a bottom electrode on a substrate; and
forming an isolation layer on the bottom electrode, defining a plurality of pixel openings in the isolation layer, and exposing the bottom electrode from the plurality of pixel openings;
wherein in the operation of screening the plurality of hollow nanospheres of different sizes so that the plurality of hollow nanospheres of different sizes are stacked in layers on a substrate according to their sizes, a multilayer molecular sieve structure is used to screen the plurality of hollow nanospheres of different sizes in sequence;
wherein the operation of forming a light-emitting element comprises forming a top electrode to form the light-emitting element.

16. The method as recited in claim 11, wherein the operation of screening the plurality of hollow nanospheres of different sizes so that the plurality of hollow nanospheres of different sizes are stacked in layers on a substrate according to their sizes comprises:
stacking a plurality of layers of molecular sieve membranes having different screening sizes to form a multilayer molecular sieve structure;
using the multilayer molecular sieve structure to screen out a layer of hollow nanospheres having the smallest size, and forming a layer of light-emitting material on the bottom electrode;
removing the molecular sieve membrane with the smallest screening size, and using the multilayer molecular sieve structure to continue screening out the hollow nanospheres having the smallest size among the remaining hollow nanospheres of different sizes, and forming another layer of light-emitting material;
repeating the above operations in sequence until the plurality of hollow nanospheres of different sizes are all stacked in layers on the substrate according to their sizes;
wherein the multilayer molecular sieve structure comprises a plurality of layers of molecular sieve membranes having different screening sizes, and wherein the screening sizes of the molecular sieve membranes are set in one-to-one correspondence with the sizes of the hollow nanospheres.

17. The method as recited in claim 14, wherein the light-emitting materials comprise a hole injection layer material, a hole transport layer material, a light-emitting layer material, an electron transport layer material, and an electron injection layer material; wherein the hole transport layer material is filled in the first nanosphere; wherein the hole transport layer material is filled in the second nanosphere; wherein the light-emitting layer material is filled in the third nanosphere; wherein the electron transport layer material is filled in the fourth nanosphere; wherein the electron injection layer material is filled in the fifth nanosphere.

18. The method as recited in claim 11, wherein the operation of heating the plurality of hollow nanospheres of different sizes so that the plurality of hollow nanospheres sublime and the respective light-emitting materials in the plurality of hollow nanospheres of different sizes are stacked and distributed in layers on the substrate to form a light-emitting element comprises:
heating the substrate to a preset temperature so that each hollow nanospheres comparatively closer to the substrate sublime earlier than each another hollow nanosphere comparatively farther away from the substrate; and
forming a plurality of light-emitting material layers that are stacked one over another on the substrate.

19. A display panel, comprising a light-emitting element manufactured by a method comprising:
forming a plurality of hollow nanospheres of different sizes, wherein the plurality of hollow nanospheres are each filled with a respective light-emitting material;
disposing the plurality of hollow nanospheres of different sizes on a substrate;
screening the plurality of hollow nanospheres of different sizes so that the plurality of hollow nanospheres of different sizes are stacked in layers on the substrate according to their sizes, wherein the smaller the size of a hollow nanosphere, the closer the hollow nanosphere is to the substrate;
heating the plurality of hollow nanospheres of different sizes so that the plurality of hollow nanospheres sublime, and the light-emitting materials in the plurality of hollow nanospheres of different sizes are stacked and distributed in layers on the substrate to form the light-emitting element;
wherein the hollow nanospheres of an equal size are filled with an identical light-emitting material, and wherein the hollow nanospheres of different sizes are filled with different light-emitting materials; wherein the light-emitting materials are each an organic light-emitting material.
